(19) United States
(12) Patent Application Publication
(10) Pub. No.: US 2020/0122269 A1
(43) Pub. Date: Apr. 23, 2020

(54) METHOD OF FORMING A SEAL, METHOD OF MANUFACTURING A SEALED UNIT, A SEALED UNIT, AND APPARATUS FOR FORMING A SEAL

(71) Applicant: M-SOLV LIMITED, Oxford, Oxforshire (GB)

(72) Inventor: Adam North BRUNTON, Oxford (GB)

(73) Assignee: M-SOLV LIMITED, Oxford, Oxfordshire (GB)

(21) Appl. No.: 16/606,524

(22) PCT Filed: Apr. 18, 2018
(86) PCT No.: PCT/GB2018/051016

§ 371 Date: Oct. 18, 2019

(30) Foreign Application Priority Data
Apr. 19, 2017 (GB) 1706185.4

(51) Int. Cl. B23K 26/20; C03C 27/08; H01L 51/52; H01L 51/44

(52) U.S. Cl. CPC B23K 26/206; H01L 51/448; H01L 51/5246; C03C 27/08

(57) ABSTRACT

Methods and apparatus for forming a seal are disclosed. In one arrangement, a first panel and a second panel are provided. A sealer material is present between the first panel and the second panel. The sealer material is in contact with the first panel and the second panel along all of a seal path. A first heating process is performed to heat metal particles derived from the sealer material along the seal path to cause fusing of the metal particles along the seal path. A second heating process is performed, separately from the first heating process, to provide a continuous weld along the seal path between the fused metal particles and the first panel and between the fused metal particles and the second panel, thereby generating a seal along the seal path.

The invention relates to methods and apparatus for forming seals between panels, particularly for use in manufacturing sealed units such as vacuum insulation glass assemblies, or assemblies comprising panels containing electronics that are sensitive to atmospheric humidity, such as OLED display devices, OLED lighting, smart windows, or perovskite and/or organics based photovoltaic systems.

Glass frit sealing is a known technique for providing a sealed region between transparent panels. A glass frit is deposited in a closed loop track between the panels and heated to form a glass weld along the line of the closed loop track, thereby providing the sealed region. A furnace may be used to provide the heating. This approach is difficult where the sealing region forms part of a large object (e.g. a large window unit or large display panel), due to the need to provide a correspondingly large furnace. Furthermore, since all of the object to be treated needs to be inside the furnace, components which are sensitive to high temperatures (e.g. delicate electronics in a display panel) cannot be present, which may limit the range of objects that can be treated.

Laser glass frit sealing is an alternative technique in which a laser is used to apply heat to the glass frit locally. This may avoid the need to put the whole object inside a furnace and can avoid excessive heating of delicate components, as long as they are positioned sufficiently far away from the glass frit. However, the temperatures that need to be applied to the glass frit for the welding process are still relatively high (typically 400-500 degrees C.) and significant pre-heating by a furnace (e.g. to within a 100 degrees C. or so of the final temperature) may still be required. Applying such temperatures locally can generate significant thermal stresses due to differential thermal expansion and contraction. Such stresses have been found to limit the range of situations in which laser glass frit sealing can be used effectively, and/or to reduce manufacturing yield, reliability and/or product longevity.

EP 2 124 254 A1 discloses a sealing method for hermetically sealing a piezoelectric element. The method uses a specially formulated metal paste comprising a metal powder and an organic solvent. A sealing method comprises the following steps in order: (a) applying the metal paste to a base member or cap member; (b) drying the metal paste and sintering at 80° C. to 300° C. to form a metal powder sintered body; and (c) disposing the cap member onto the base member with the metal powder sintered body therebetween, and bonding the base member and the cap member by applying pressure from one direction or from both directions while heating at least the metal powder sintered body. The pressure and heat densifies the metal powder sintered body to form a dense bonded part. The approach of EP 2 124 254 A1 thus again requires relatively high temperatures during the bonding process, which may restrict use to where components which are sensitive to high temperatures are not present. The pressures required during bodying may induce significant localized stresses, which may limit the range of situations in which the bonding can be used. Finally, careful design of the metal paste is required to achieve the desired functionality.

It is an object of the invention to provide methods and apparatus for forming seals and/or manufacturing sealed units that at least partially address one or more of the problems with the prior art.

According to an aspect of the invention, there is provided a method of forming a seal, the method comprising: providing a first panel and a second panel, wherein a sealer material is present between the first panel and the second panel, the sealer material is in contact with the first panel and the second panel along all of a seal path, performing a first heating process to heat metal particles derived from the sealer material along the seal path, while the sealer material is in contact with the first panel and the second panel along all of the seal path, to cause fusing of the metal particles along the seal path; and performing a second heating process, separate from the first heating process, to provide a continuous weld along the seal path between the fused metal particles and the first panel and between the fused metal particles and the second panel, thereby generating a seal along the seal path, wherein the second heating process is performed using a laser.

Thus, a method is provided in which a sealer material containing metal particles is positioned between two panels in such a way as to contact both panels all along a seal path. This can be achieved easily because the metal particles can flow past each other within the matrix (in contrast to metal atoms in a solid metal). By fusing the metal particles after the sealer material has been thus provided it is possible to create a continuous layer of metal along the seal path. The continuous layer of metal can then be welded to the panels to create a seal along the seal path. This process can be performed with much lower levels of heating than the equivalent process using a glass frit, thereby reducing thermal stresses to the panels and/or nearby functional components to be sealed between the panels, and avoiding any need to position the panels within a furnace. The permeability of the seal is typically lower than alternatives such as thermoset plastic edge seals, thereby providing greater longevity in products such as OLED lighting and 3^{rd} generation PV applications sensitive to oxygen/moisture ingress, while not needing the high temperature processing associated with glass frits which is often incompatible with functional elements of the products.

Fusing the metal particles only after the two panels have been brought together makes it possible to produce an optically accurate interface between the fused metal particles and the first and second panels, thereby making efficient laser welding along the seal possible in the second heating process. This approach avoids the need for difficult and time-consuming glass polishing techniques, which might otherwise be necessary to make laser welding through the panels effective. In an embodiment, the fusing of the metal particles by the first heating process along the seal path is such that a largest gap between the fused metal particles and the first panel or the second panel along the seal path has a largest dimension that is smaller than 5 microns, optionally less than 2 microns, optionally less than 1 micron, optionally less than 500 nm, optionally less than 300 nm, optionally less than 150 nm.

In an embodiment the welding is performed by laser welding using a laser configured to provide pulses having a pulse length of less than 50 ps. This approach allows the welding to be achieved reliably and with very low heat loads.

In an embodiment the method comprises: depositing the sealer material on the first panel; heating the sealer material to remove a portion of the sealer material, thereby increasing the stiffness of the sealer material; and moving either or both of the first panel and the second panel so that the first panel and the second panel are brought into a facing configuration in which the sealer material is in contact with the first panel and the second panel along all of the seal path. This approach allows the sealer material to be deposited efficiently while in a relatively low viscosity state. The subsequent heating increases the stiffness of the sealer material to a level which is suitable for resisting compression by the first panel and the second panel to an optimal extent (i.e. to allow deformation to compensate for imperfections in the panels or misalignments without excessive clamping forces being needed, while at the same time not being so liquid that the sealer material spreads excessively when squeezed between the panels).

In an alternative aspect, there is provided an apparatus for forming a seal, comprising: a deposition unit configured to deposit a sealer material along a seal path on a first panel; a panel handler configured to move either or both of the first panel and the second panel so that the first panel and second panel are brought into a facing configuration in which the sealer material is in contact with the first panel and the second panel along all of a seal path; a first heating unit configured to heat metal particles derived from the sealer material along the seal path, while the sealer material is in contact with the first panel and the second panel along all of the seal path, to cause fusing of the metal particles along the seal path; and a second heating unit configured to provide a continuous weld along the seal path between the fused metal particles and the first panel and between the fused metal particles and the second panel, thereby generating a seal along the seal path, wherein the second heating unit comprises a laser configured to provide the continuous weld.

The invention will now be further described, by way of example, with reference to the accompanying drawings, in which:

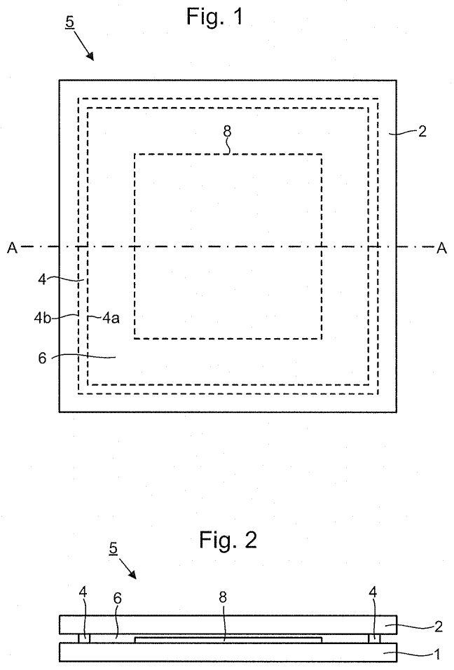

FIG. 1 is a schematic top view of a sealed unit formed using a method of an embodiment;

FIG. 2 is a schematic side sectional view of the sealed unit of FIG. 1 along line A-A;

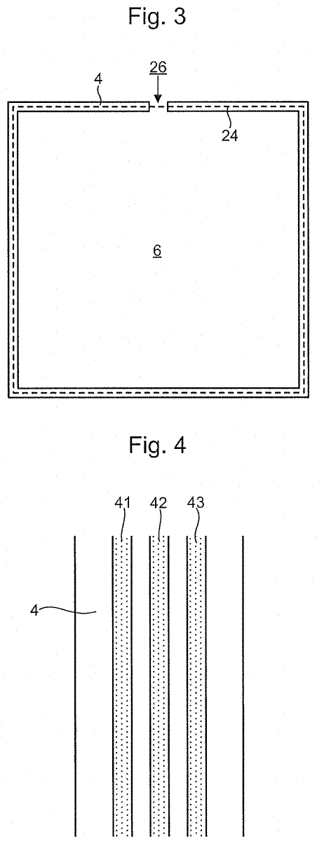

FIG. 3 depicts an example seal path forming at least 95% of a closed loop;

FIG. 4 is a schematic top view of a portion of a seal path viewed through a panel, showing plural parallel weld lines in sealer material;

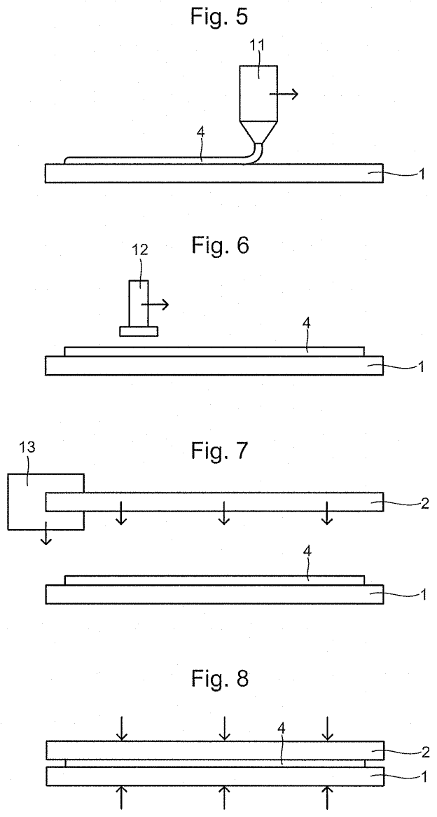

FIGS. 5-11 are schematic side views depicting stages in an example method of forming a seal;

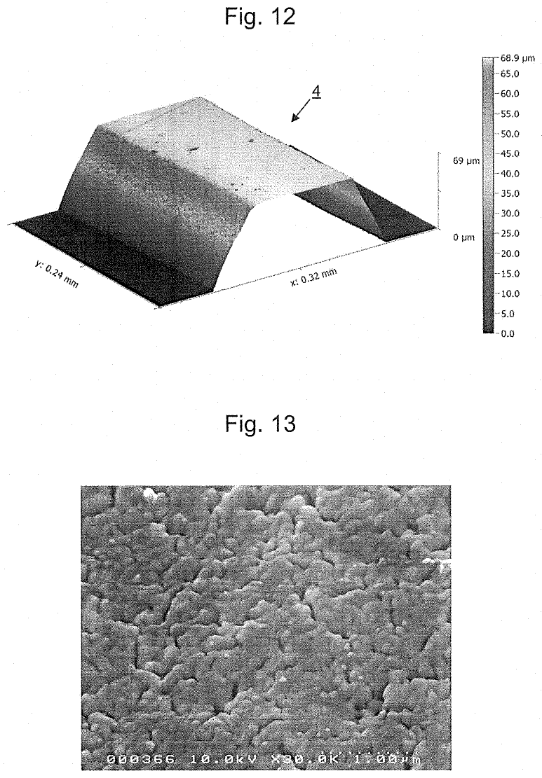

FIG. 12 depicts data obtained from a white-light interferometer measuring a surface profile of a portion of the sealer material after the sealer material has been processed to increase the stiffness of the sealer material and a subsequent flattening of the sealer material caused by panels being brought into a facing configuration sandwiching the sealer material between them;

FIG. 13 is an SEM image showing a surface of the sealer material after fusing of metal particles within the sealer material;

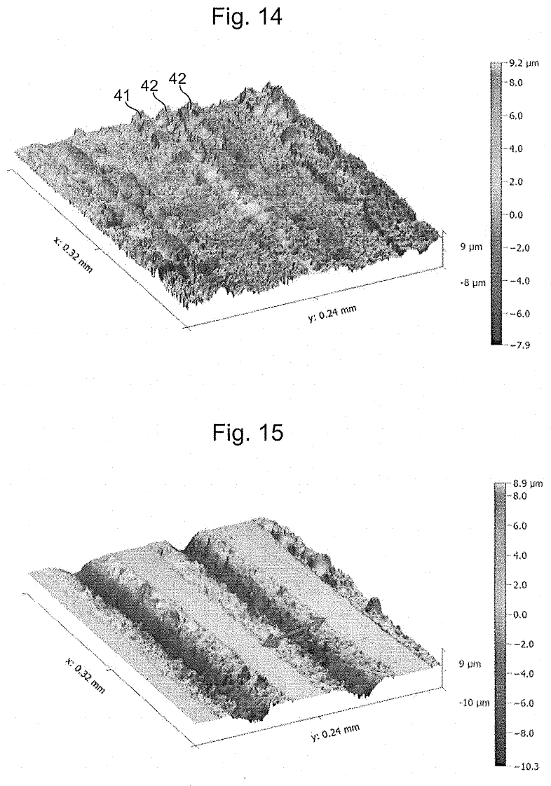

FIG. 14 depicts data obtained from a white-light interferometer measuring a surface profile of a welded portion of the sealer material after removal of the welded portion from a corresponding portion of the panel; and

FIG. 15 depicts data obtained from a white-light interferometer measuring a surface profile of the portion of the panel corresponding to the welded portion of the sealer material shown in FIG. 14 after removal of the welded portion from the corresponding portion of the panel.

Embodiments relate to forming a seal between a first panel 1 and a second panel 2. The seal may be used to manufacture a sealed unit 5. The sealed unit may form part of a vacuum insulation glass assembly, an OLED display device, OLED lighting, a smart window, or a perovskite and organics based photovoltaic system, for example.

An example sealed unit 5 is depicted schematically in FIGS. 1 and 2. The sealed unit 5 comprises a first panel 1 and a second panel 2. A sealer material 4 is provided in between the first panel 1 and the second panel 2. The combination of the sealer material 4, the first panel 1 and the second panel 2 seal a region 6 within the sealed unit 5. Electronics 8 to be protected from an outside environment may be provided within the region 6.

The sealer material 4 is deposited along a seal path. The first panel, second panel and sealer material are configured such that the sealer material 4 is in contact with the first panel 1 and the second panel 2 along all of the seal path. Furthermore, as will be described in further detail below, the sealer material 4 is laser welded to the panels so that a seal is formed between the sealer material 4 and the first panel 1 and between the sealer material 4 and the second panel 2 along all of the seal path.

In various embodiments the seal path at least partially encircles the region 6 between the first panel 1 and the second panel 2. The seal path may for example comprise at least 95% of a closed loop 24, optionally at least 99%. An example of such a seal path is shown in FIG. 3. Alternatively, as depicted in FIG. 1, the seal path may form a complete closed loop (a rectangle in the example shown, but other shapes could be used). The seal along the seal path may be formed by laser welding along a single line along the seal path. Alternatively, as depicted schematically in FIG. 4, the seal path may be formed by laser welding along plural parallel lines 41-43. Welding along plural parallel lines 41-43 increases the reliability of the seal.

Typically the first panel 1 and the second panel 2 will have substantially complementary shapes (i.e. so that if the respective surfaces were perfectly formed and oriented they could be made to be perfectly parallel to each other). In an embodiment, the first panel 1 and the second panel 2 are both substantially planar. In another embodiment, the first panel 1 and the second panel 2 are curved with a constant radius of curvature common to both panels. Either or both of the first panel 1 and the second panel 2 may be transparent to radiation in the visible spectrum. Additionally, at least one of the first panel 1 and the second panel 2 should be sufficiently transparent to the radiation used to perform the laser welding (“second heating process”—see below).

Either or both of the first panel 1 and the second panel 2 may comprise a transparent glass material, such as a silicate glass. For cost and convenience the silicate glass preferably comprises a soda-lime glass. Soda-lime glass is well known in the art and may for example be composed approximately of 75% silicon dioxide (SiO₂), sodium oxide (Na₂O) from sodium carbonate (Na₂CO₃), calcium oxide, also called lime (CaO), and several minor additives. Soda-lime glass is susceptible to breakage when exposed to large variations in temperature and temperature gradients. The extremely localised nature of heating required to perform the methods disclosed herein avoid such problems and allow soda-lime glass to be used with high reliability and yield. Other transparent glass materials could be used, however, including for example materials with coefficients of thermal expansion lower than soda-lime glass, such as borosilicate glass, fused silica, etc.

The first panel 1 and the second panel 2 have respective surfaces (e.g. the upper surface of the first panel 1 and the lower surface of the second panel 2 in the figures) that face into a region 6 between the first panel 1 and the second panel 2 that is to be sealed at a later stage. The separation between the respective surfaces may be nominally constant within the region 6.

The seal provided along the seal path forms part of the seal around the region 6 when it is eventually sealed completely. The final seal may be made after a desired gas or vacuum state is established within the region 6. Thus, a method step prior to final sealing may comprise changing a pressure or composition of gas within the region 6. This may be achieved by connection of a suitable vacuum pump or gas source to a port leading into the region 6. The port may access the region 6 from the side (e.g. through a gap such as gap 26 in FIG. 3 where the sealer material 4 did not complete the closed loop 24, or through a small hole in the first panel 1 or in the second panel 2). When the desired gas or vacuum state is established, the port is sealed.

Methods and apparatus for forming a seal and manufacturing a sealed unit 5 will now be described with reference to FIGS. 5-15.

FIG. 5 depicts an initial step in which a deposition unit 11 deposits the sealer material 4 along a seal path on the first panel 1. The nature of the deposition process is not particularly limited. In one embodiment the deposition unit 11 operates by moving a syringe containing the sealer material 4 along the seal path and driving the sealer material 4 out of the syringe at an appropriate rate using a compressed air supply system connected to the syringe. Other printing techniques may be used.

In an embodiment the sealer material 4 comprises metal particles held in a matrix. The nature of the matrix and the metal particles is not particularly limited as long as they can perform their respective roles to form the seal between the first panel 1 and the second panel 2, as described below. In an embodiment the matrix is non-metallic. At the point of being deposited, the sealer material 4 needs to have relatively low viscosity, so that it can be deposited efficiently. Later on, as will be described in further detail below, the sealer material 4 will need to provide various other functions, such as allowing the first panel 1 and the second panel 2 to be brought into contact with the sealer material 4 in such a way that there is a continuous contact with the sealer material and both panels along all of a seal path, allowing fusing (sintering) of the metal particles together and, subsequently, allowing a seal to be formed by welding of the fused metal particles to the first and second panels 1, 2.

In an embodiment, the metal particles comprise one or more of the following: silver, gold, nickel, aluminium and/or copper. Preferably the metal particles comprise silver and/or copper. The metal particles may comprise metal microparticles and/or metal nanoparticles. The matrix may be a liquid or paste. The matrix may comprise an organic carrier or a combination of organic carriers, for example, the matrix may comprise ethanol and/or ethylene glycol. In an embodiment, the matrix comprises one or more of the following: epoxies, acrylics and polyurethanes.

In a subsequent step, as depicted in FIG. 6, a heating unit 12 removes (by heating) a portion of the sealer material, for example a volatile or easily evaporated component of a matrix holding metal particles of the sealer material (e.g. an organic carrier or combination of organic carriers), or all of the matrix. The removal of the portion of the sealer material increases the stiffness of the sealer material 4 (increases a viscosity of the sealer material 4). The heating may be applied in various ways. Typically, only relatively low temperatures will be needed to achieve adequate removal of the volatile component, for example in the region of 100 degrees C. for a few minutes (e.g. 1-10 minutes). The heating may be applied simultaneously to the whole of the first panel 1 and the second panel 2, or may be applied locally, for example using a mobile infrared lamp or laser.

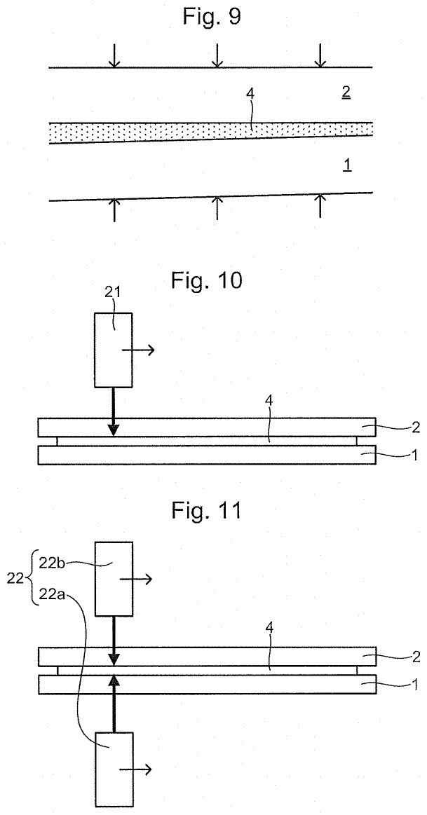

Increasing the stiffness of the sealer material 4 desirably increases a resistance to deformation of the sealer material 4 during a subsequent step, depicted schematically in FIGS. 7-9, in which the first panel 1 and the second panel 2 are brought into a facing configuration. The facing configuration is such that the first panel 1 and the second panel 2 squeeze the sealer material 4 between them to ensure full contact between the sealer material 4 and both of the first panel 1 and the second panel 2 along all of the seal path. In the embodiment shown, this process is performed using a panel handler 13. The panel handler 13 is capable of gripping one or both of the first panel 1 and the second panel 2 and providing controlled relative movement between them. The panel handler 13 moves either or both of the first panel 1 and the second panel 2 so that the first panel 1 and the second panel 2 are in the facing configuration. In the example of FIG. 7 the panel handler 13 grips the second panel 2 only, and moves the second panel 2 downwards onto the first panel 1. The first panel 1 and the second panel 2 are then pressed together as depicted in FIG. 8. The facing configuration is such that the sealer material 4 is in contact with the first panel and the second panel along all of a seal path. This is achieved by the sealer material 4 deforming slightly along the seal path, as the first panel 1 and the second panel 2 are pressed together. The deformation compensates for irregularities in the first panel 1, irregularities in the second panel 2, and/or misalignment of the first panel 1 relative to the second panel 2 (as depicted schematically in FIG. 9). In an embodiment, the stiffness of the sealer material 4 after the heating of the sealer material is such that a height of the sealer material 4 can be reduced by at least 5%, optionally at least 10%, optionally at least 25%, optionally at least 50%, optionally at least 75%, optionally at least 90%, during the moving of either or both of the first panel 1 and the second panel 2 to bring the first panel 1 and the second panel 2 into the facing configuration, without risk of damage to the first panel 1 or second panel 2, or risk of interruption to the continuity of the sealer material 4 along the seal path. FIG. 12 shows a typical surface profile of sealer material 4 between the first panel 1 and the second panel 2 when they are in the facing configuration. Deformation (flattening) of a top surface of the bead of sealer material 4 is seen but no excessive lateral spreading of the sealer material 4.

As depicted in FIG. 10, in a subsequent step a heating unit 21 heats metal particles derived from the sealer material along the seal path to cause fusing of the metal particles along the seal path. The metal particles may be derived from the sealer material for example by removing at least a portion of a matrix holding the metal particles, or by initiating a chemical reaction resulting in generation or precipitation of the metal particles from a component of the sealer material (e.g. from an organometallic component). The heating may be referred to as a first heating process (a second heating process is described below). In one embodiment, the heating is performed in an oven in a temperature range of 150-200 degrees C. for a few 10s of minutes (e.g. 50 minutes for micro/nanoparticle based sealant materials). The fusing of the metal particles effectively forms a continuous path of metal along the seal path. The continuous path of metal is in continuous contact with the first panel 1 along one side and in continuous contact with the second panel 2 along the other side. A seal has not yet been formed robustly or at all by this fusing process. The fusing process merely provides the continuous path of metal that is necessary to create a seal using the laser welding of a subsequent step. In an embodiment, the fusing of the metal particles by the first heating process along the seal path is such that a largest gap between the fused metal particles and the first panel or the second panel along the seal path has a largest dimension that is smaller than 5 microns, optionally less than 2 microns, optionally less than 1 micron, optionally less than 500 nm, optionally less than 300 nm, optionally less than 150 nm. FIG. 13 is an SEM image showing the continuous metallic surface of the sealer material treated in this way.

In an embodiment, the heating unit 21 comprises a laser, for example a diode-pumped solid state laser, a fibre laser, a laser diode, or a CO₂ laser. The laser may be configured to provide a continuous wave (CW) laser beam, or a quasi-continuous wave (quasi-CW) laser beam. Alternatively, the laser may be configured to provide a pulsed laser beam. The laser preferably provides a laser beam with a wavelength of in the range of approximately 500 nm to 11000 nm. The heating unit 21 may be moveably mounted and/or beam scanning optics may be provided in order for a laser spot from the heating unit 21 to be moved along all of the seal path. The heating unit 21 could alternatively comprise an IR lamp, a microwave source, or an ultrasound source.

As depicted in FIG. 11, in a subsequent step a heating unit 22 provides a continuous weld along the seal path. The continuous weld is provided both between the fused metal particles and the first panel 1 and between the fused metal particles and the second panel 2 (i.e. on both sides of the sealer material 4). The continuous weld forms a seal along the seal path. The seal is such as to prevent passage of gas between an inner surface 4a of the sealer material 4 (see FIG. 1) and an outer surface 4b of the sealer material 4 directly past the sealer material 4. The welding process is thus such that there are no gaps between the sealer material 4 and either of the first panel 1 and the second panel 2.

Laser welding of glass to metal has recently been demonstrated in a general context. The laser welding can be performed using a laser configured to provide a pulse length of less than 50 ps, optionally less than 15 ps, optionally less than 1 ps, optionally less than 500 fs. The laser preferably provides a laser beam with a wavelength of approximately 500 nm to 1100 nm. Repetition rates may typically be in the range of 100 kHz to 2 MHz. Relatively high repetition rates are desirable to allow thermal accumulation between successive pulses. Each pulse needs to arrive before the thermal energy from a preceding pulse has dissipated, which typically takes of the order of a microsecond. Furthermore, since the required relative geometrical displacement between successive spots is likely to be fixed, increasing the repetition rate allows the processing to progress more quickly along the welding line, thereby improving throughput. The heating unit 22 may comprise a first heating unit sub-unit 22a configured to provide welding at an interface between the sealer material 4 and the first panel 1 and a second heating unit sub-unit 22b configured to provide welding at an interface between the sealer material 4 and the second panel 2. Thus, the welding may be achieved by directing a laser onto the sealer material 4 from both sides. The heating unit 22 (including, if provided, the first heating unit sub-unit 22a and the second heating unit sub-unit 22b) may be moveably mounted and/or beam scanning optics may be provided in order for a laser spot or laser spots from the heating unit 22 to be moved along all of the seal path.

The amount of energy deposited into the sealer material 4 using such laser parameters is extremely small, typically an order of magnitude smaller for example than the energy required to perform the fusing of the metal particles in the preceding step (performed by the heating unit 21). Pulse energy, repetition rate, laser spot size and the relative speed of movement (spot speed) between the laser spot and the interface to be welded are selected/controlled to optimise the welding process. The pulse repetition rate and spot speed are such that laser spots associated with individual pulses overlap along the seal path.

Detailed techniques are described for example in the following two publications: 1) Zhang et al., APPLIED OPTICS Vol. 54, No. 30 8957-8961 (20 Oct. 2015); and 2) Carter et al., APPLIED OPTICS Vol. 53, No. 19 4233-4238 (1 Jul. 2014). Zhang et al. teaches for example that an 800 nm Ti:sapphire chirped pulse amplification femtosecond laser system with a repetition rate of 1 kHz and a pulse duration of 160 fs, focused to a spot of diameter 8 microns, can be used. Pulse energies in the range of 1-35 microJoules were used, with a relative speed of movement of the spot of 30-800 microns per second. Carter et al. used a 1030 nm laser with 7.12 ps pulses and a repetition rate of 400 kHz. Laser power was 1.79 W with a spot size of 1.2 microns and a spot speed of 1 mm per second.

The techniques disclosed in Zhang et al. and Carter et al. are applied to solid metals rather than to metals formed from a sealer material 4 that has been processed to fuse metal particles together. It is difficult to perform the laser welding over large distances where a solid metal is used because it is difficult to ensure that the solid metal is in continuous contact with the glass surface over all of the line to be welded. Any gaps that do exist need to be small enough that both interfaces are still within the focal depth of the laser and are small enough to contain any plasma. If the plasma escapes, ablation rather than welding will occur, which will disrupt the seal and damage the glass and/or metal. One approach to addressing this problem has been to clamp the metal and the glass together, but this can introduce undesirable stresses into the glass and/or be inconvenient. The inventors have recognised that these challenges can be overcome by providing a sealer material 4 comprising metal particles instead of a solid metal, and processing the sealer material 4 after the sealer material 4 has been sandwiched by the first and second panels 1, 2, to fuse the metal particles together ready to form the welding. A continuous contact between the fused metal particles and the surfaces of the first and second panels 1, 2 against which the welding is to be performed can be achieved reliably over large distances without requiring large clamping forces.

The effectiveness of the welding process is illustrated in the surface profiles shown in FIGS. 14 and 15. The figures show how the welding process causes the metal of the sealer material 4 to become significantly embedded within the material of the panel, forming a continuous trench in the panel along a seal path. The example shown is of the type discussed above with reference to FIG. 4, in which plural parallel weld lines 41-43 are formed along the seal path. The plural weld lines 41-43 are visible in FIG. 14. The plural weld lines 41-43 are not visible in FIG. 15 but this may be due to damage caused by the pulling apart of the welded portions in order to generate the images.

Additional embodiments are disclosed in the following numbered clauses.

1. A method of forming a seal, the method comprising:

providing a first panel and a second panel, wherein a sealer material is present between the first panel and the second panel, the sealer material is in contact with the first panel and the second panel along all of a seal path,

performing a first heating process to heat metal particles derived from the sealer material along the seal path, while the sealer material is in contact with the first panel and the second panel along all of the seal path, to cause fusing of the metal particles along the seal path; and

performing a second heating process, separate from the first heating process, to provide a continuous weld along the seal path between the fused metal particles and the first panel and between the fused metal particles and the second panel, thereby generating a seal along the seal path, wherein:

the second heating process is performed using a laser.

2. The method of clause 1, wherein the fusing of the metal particles by the first heating process along the seal path is such that a largest gap between the fused metal particles and the first panel or the second panel along the seal path has a largest dimension that is smaller than 500 nm.
3. The method of clause 1 or 2, wherein the second heating process is performed using a laser configured to provide pulses having a pulse length of less than 50 ps.
4. The method of any preceding clause, wherein the providing of the first panel and the second panel comprises the following steps in order:

depositing the sealer material on the first panel;

heating the sealer material to remove a portion of the sealer material, thereby increasing the stiffness of the sealer material; and

moving either or both of the first panel and the second panel so that the first panel and the second panel are brought into a facing configuration in which the sealer material is in contact with the first panel and the second panel along all of the seal path.

5. The method of clause 4, wherein the stiffness of the sealer material after said heating of the sealer material is such that a height of the sealer material can be reduced by at least 5% during the moving of either or both of the first panel and the second panel to bring the first panel and the second panel into the facing configuration, thereby to compensate for one or more of: irregularities in the first panel, irregularities in the second panel, and misalignment of the first panel relative to the second panel.
6. The method of any preceding clause, wherein the seal path at least partially encircles a region between the first panel and the second panel.
7. The method of clause 6, wherein the seal path comprises at least 95% of a closed loop.
8. The method of clause 6 or 7, wherein the continuous weld is provided along plural parallel lines along the seal path.
9. The method of any preceding clause, wherein the metal particles comprise one or more of the following: silver, gold, nickel, aluminium, copper.
10. The method of any preceding clause, wherein the metal particles comprise metal microparticles or metal nanoparticles.
11. The method of any preceding clause, wherein the sealer material comprises the metal particles held in a matrix.
12. The method of clause 11, wherein the matrix comprises a liquid or paste.
13. The method of any preceding clause, further comprising changing a pressure or composition of gas within a region at least partially encircled by the seal path and, subsequently, sealing said region.
14. The method of any preceding clause, wherein either or both of the first panel and the second panel are transparent to radiation in the visible spectrum.
15. The method of any preceding clause, wherein either or both of the first panel comprises a transparent glass material, preferably a silicate glass, more preferably a soda-lime glass.
16. A method of manufacturing a sealed unit comprising a first panel and a second panel, the method comprising forming a seal between the first panel and the second panel using the method of any preceding clause.
17. A sealed unit manufactured using the method of clause 16.
18. An apparatus for forming a seal, comprising:

a deposition unit configured to deposit a sealer material along a seal path on a first panel;

a panel handler configured to move either or both of the first panel and the second panel so that the first panel and second panel are brought into a facing configuration in which the sealer material is in contact with the first panel and the second panel along all of a seal path;

a first heating unit configured to heat metal particles derived from the sealer material along the seal path, while the sealer material is in contact with the first panel and the second panel along all of the seal path, to cause fusing of the metal particles along the seal path; and

a second heating unit configured to provide a continuous weld along the seal path between the fused metal particles and the first panel and between the fused metal particles and the second panel, thereby generating a seal along the seal path,

wherein the second heating unit comprises a laser configured to provide the continuous weld.

19. The apparatus of clause 18, wherein the laser is configured to provide pulses having a pulse length of less than 50 ps.
20. The apparatus of clause 18 or 19, further comprising:

a third heating unit configured to remove by heating a portion of the sealer material, thereby increasing the stiffness of the sealer material, wherein:

the panel handler is configured to move either or both of the first panel and the second panel into the facing configuration after the stiffness of the sealer material has been increased by the third heating unit.

21. The apparatus of any of clauses 18-20, wherein the seal path at least partially encircles a region between the first panel and a second panel.
22. The apparatus of clause 21, further comprising a gas control and sealing device configured to change a pressure or composition of gas within the region at least partially encircled by the seal path and, subsequently, seal said region.

1. A method of forming a seal, the method comprising:
providing a first panel and a second panel, wherein a sealer material is present between the first panel and the second panel, the sealer material is in contact with the first panel and the second panel along all of a seal path,
performing a first heating process to heat metal particles derived from the sealer material along the seal path, while the sealer material is in contact with the first panel and the second panel along all of the seal path, to cause fusing of the metal particles along the seal path; and
performing a second heating process, separate from the first heating process, to provide a continuous weld along the seal path between the fused metal particles and the first panel and between the fused metal particles and the second panel, thereby generating a seal along the seal path, wherein:
the second heating process is performed using a laser.

2. The method of claim 1, wherein the fusing of the metal particles by the first heating process along the seal path is such that a largest gap between the fused metal particles and the first panel or the second panel along the seal path has a largest dimension that is smaller than 5 microns.

3. The method of claim 1, wherein the second heating process is performed using a laser configured to provide pulses having a pulse length of less than 50 ps.

4. The method of claim 1, wherein the providing of the first panel and the second panel comprises the following steps in order:
depositing the sealer material on the first panel;
heating the sealer material to remove a portion of the sealer material, thereby increasing the stiffness of the sealer material; and
moving either or both of the first panel and the second panel so that the first panel and the second panel are brought into a facing configuration in which the sealer material is in contact with the first panel and the second panel along all of the seal path.

5. The method of claim 4, wherein the stiffness of the sealer material after said heating of the sealer material is such that a height of the sealer material can be reduced by at least 5% during the moving of either or both of the first panel and the second panel to bring the first panel and the second panel into the facing configuration, thereby to compensate for one or more of: irregularities in the first panel, irregularities in the second panel, and misalignment of the first panel relative to the second panel.

6. The method of claim 1, wherein the seal path at least partially encircles a region between the first panel and the second panel.

7. The method of claim 6, wherein the seal path comprises at least 95% of a closed loop.

8. The method of claim 6 or 7, wherein the continuous weld is provided along plural parallel lines along the seal path.

9. The method of claim 1, wherein the metal particles comprise one or more of the following: silver, gold, nickel, aluminium, copper.

10. The method of claim 1, wherein the metal particles comprise metal microparticles or metal nanoparticles.

11. The method of claim 1, wherein the sealer material comprises the metal particles held in a matrix.

12. The method of claim 11, wherein the matrix comprises a liquid or paste.

13. The method of claim 1, further comprising changing a pressure or composition of gas within a region at least partially encircled by the seal path and, subsequently, sealing said region.

14. The method of claim 1, wherein either or both of the first panel and the second panel are transparent to radiation in the visible spectrum.

15. The method of claim 1, wherein either or both of the first panel comprises a transparent glass material, preferably a silicate glass, more preferably a soda-lime glass.

16. A method of manufacturing a sealed unit comprising a first panel and a second panel, the method comprising forming a seal between the first panel and the second panel using the method of claim 1.

17. A sealed unit manufactured using the method of claim 16.

18. An apparatus for forming a seal, comprising:
a deposition unit configured to deposit a sealer material along a seal path on a first panel;
a panel handler configured to move either or both of the first panel and the second panel so that the first panel and second panel are brought into a facing configuration in which the sealer material is in contact with the first panel and the second panel along all of a seal path;
a first heating unit configured to heat metal particles derived from the sealer material along the seal path, while the sealer material is in contact with the first panel and the second panel along all of the seal path, to cause fusing of the metal particles along the seal path; and
a second heating unit configured to provide a continuous weld along the seal path between the fused metal particles and the first panel and between the fused metal particles and the second panel, thereby generating a seal along the seal path,
wherein the second heating unit comprises a laser configured to provide the continuous weld.

19. (canceled)

20. The apparatus of claim 18, further comprising:
a third heating unit configured to remove by heating a portion of the sealer material, thereby increasing the stiffness of the sealer material, wherein:
the panel handler is configured to move either or both of the first panel and the second panel into the facing configuration after the stiffness of the sealer material has been increased by the third heating unit.

21. The apparatus of claim 18, wherein the seal path at least partially encircles a region between the first panel and a second panel, and the apparatus further comprising a gas control and sealing device configured to change a pressure or composition of gas within the region at least partially encircled by the seal path and, subsequently, seal said region.

22. (canceled)
